(19) United States
(12) Patent Application Publication
(10) Pub. No.: US 2010/0110747 A1
(43) Pub. Date: May 6, 2010

(54) SEMICONDUCTOR MEMORY DEVICE

(75) Inventors: Yuji Nakaoka, Kanagawa (JP); Shin-ichi Iwashita, Kanagawa (JP)

Correspondence Address: Solaris Intellectual Property Group, PLLC, 401 Holland Lane, Suite 407, Alexandria, VA, 22314, US

(73) Assignee: LIQUID DESIGN SYSTEMS, INC., Kawasaki-shi, Kanagawa (JP)

(21) Appl. No.: 12/525,310

(22) PCT Filed: Jan. 31, 2007
(86) PCT No.: PCT/JP2007/051602

§ 371 Date: Jan. 15, 2010

(30) Foreign Application Priority Data
Aug. 10, 2005 (JP) 2005-232160

(51) Int. Cl. G11C 5/02; G11C 5/14; G11C 8/00; G11C 7/00

(52) U.S. Cl. 365/51; 365/226; 365/230.03; 365/219; 365/233.1

(57) ABSTRACT

The semiconductor memory device proposed in the present invention comprises memory cells disposed in the row direction and the column direction, a plurality of first lines by which supply voltages are supplied in order to select memory cells disposed in the row direction among the plurality of cells, a plurality of second lines by which supply voltages are supplied in order to select memory cells disposed in the column direction among the plurality of cells, the data lines which input and output the data to the selected memory cells, the first power voltage supply circuit which supplies the predetermined supply voltages to the first lines corresponding with the externally input row address synchronizing with an act command, and the second power voltage supply circuit which supplies the predetermined supply voltages to the second lines corresponding with the externally input column address synchronizing with an act command. It also comprises m pieces of memory banks (m is a natural number larger than 2) which write or read the data into or from the memory cells which are selected one after another in the row or column directions, data input circuits in which multiple bits of serial data which is larger than 512 bits to be written in the m pieces of memory banks, data output circuits which reads the data from the m pieces of memory banks and output in a form of multiple bits of serial data which is larger than 512 bits, and data conversion circuits which convert the serial data input in the data input circuits to parallel data so that it can be written in each memory bank or to convert each parallel data read from each memory bank to serial data so that such data are supplied to the data output circuits.

### TECHNICAL FILED

This invention is with respect to a semiconductor memory device, particularly a memory device which contains DRAM chips.

### BACKGROUND ART

Conventionally, Dynamic Random Access Memories (DRAMs) are commonly used as semiconductor memory devices temporarily storing data. Compared to Static Random Access Memories (SRAMs), DRAMs have simpler circuits, can be easily integrated, and are lower in price. Therefore, DRAMs are most commonly used as main memories in computers.

However, in spite of above-mentioned strengths, the performance of random access by DRAMs is not good. In order to deal with such weakness, there are newly proposed memory products which consecutively read data with different column addresses in high speed and re-write the data. (e.g., see attached patent document 1)

The memory (DRAM) described in the patent document 1 consists of a plurality of memory cells distributed at crossing points of data lines and word lines in a matrix form and includes several sense amplifiers which search the stored data in the above-mentioned memory cells. These sense amplifiers share the input and output lines via a switch to transfer data to external systems or to write the data input from external systems. Also, there are several shared input and output lines, and by the above-mentioned switching control, the sense amplifiers can electrically connect to at least two of the shared input and output lines.

With such configuration, when one sense amplifier SAi connects to the input and output lines I/Oa and conducts data input and output, by connecting the next sense amplifier SAj to another I/Ob and starting to conduct data input and output, the data can be input and output consecutively and high-speed.

Patent document 1: Japanese Patent Application Laid-Open No. 7-282583

### DISCLOSURE OF THE INVENTION

### Problem to be Solved by the Invention

Normally, the DRAM described in the patent document 1 should wait for an act command, and then, activate the word line WLi by the row decoder XDEC, and then, after the next command arrives, it should inactivate the word line WLi.

However, if it tries to activate another word line WLi consecutively during its random access, unless the command to inactivate the word line WLi arrives, it is not able to activate the next word line WLi. Therefore, even if the technology described in the patent document 1 is utilized, the high-speed random access is not achievable.

Further, conventional DRAMs usually take 50 to 60 ns from the act command arrival to data output, so there is a need for high-speed data input and output.

In order to solve above-mentioned challenges, the present invention is proposed, and the objectives of the present invention are to enhance the random access capability of DRAMs as well as to realize a semiconductor memory device which can increase the speed of data input and output compared to conventional DRAMs.

### Means for Solving the Problem

The semiconductor memory device proposed in the present invention comprises memory cells disposed in the row direction and the column direction, a plurality of first lines by which supply voltages are supplied in order to select memory cells disposed in the row direction among the plurality of cells, a plurality of second lines by which supply voltages are supplied in order to select memory cells disposed in the column direction among the plurality of cells, the data lines which input and output the data to the selected memory cells, the first power voltage supply circuit which supplies the predetermined supply voltages to the first lines corresponding with the externally input row address synchronizing with an act command, and the second power voltage supply circuit which supplies the predetermined supply voltages to the second lines corresponding with the externally input column address synchronizing with an act command. It also comprises m pieces of memory banks (m is a natural number larger than 2) which write or read the data into or from the memory cells which are selected one after another in the row or column directions, data input circuits in which multiple bits of serial data which is larger than 512 bits to be written in the m pieces of memory banks, data output circuits which reads the data from the m pieces of memory banks and output in a form of multiple bits of serial data which is larger than 512 bits, and data conversion circuits which convert the serial data input in the data input circuits to parallel data so that it can be written in each memory bank or to convert each parallel data read from each memory bank to serial data so that such data are supplied to the data output circuits.

In the memory banks, memory cells are disposed in the row direction and the column direction. In order to select memory cells to write the data or to read the data, the memory cells comprise first lines which provide the supply voltage in order to select memory cells in the row direction, second lines which provide the supply voltage in order to select memory cells in the column direction, and data lines to input and output the data to and from the selected memory cells.

Here, the first power voltage supply circuit provides a predetermined level of supply voltage for a certain period of time to the first lines which correspond with the externally input row address, synchronizing with the act command. In other words, the power voltage supply circuit increases the supply voltage for the first lines to a predetermined level when the act command arrives, and after a certain period of time passes, it automatically decreases the supply voltage to the original level. Therefore only one act command is required to change the voltage level. Also, the second power voltage supply circuit provides a predetermined level of supply voltage to the second lines which correspond with the externally input column address.

Thus, only one act command can change the level of the supply voltage for the first lines, and it makes it possible to control the supply voltage of many different first lines in high-speed. As a result, the random access performance is enhanced.

The data conversion circuits which convert the serial data input in the data input circuits to parallel data so that it can be written in each memory bank or to convert each parallel data read from each memory bank to serial data so that such data are supplied to the data output circuits. This way, the data input circuits which input data in the semiconductor memory device and the data output circuits which output the data from the semiconductor memory device can be kept separate, so there are no timing gaps but to burst the data writing and reading process.

### EFFECT OF THE INVENTION

The present invention enhances the random access capabilities to memory banks as well as enables high-speed writing and reading of data.

### BRIEF DESCRIPTION OF THE INVENTION

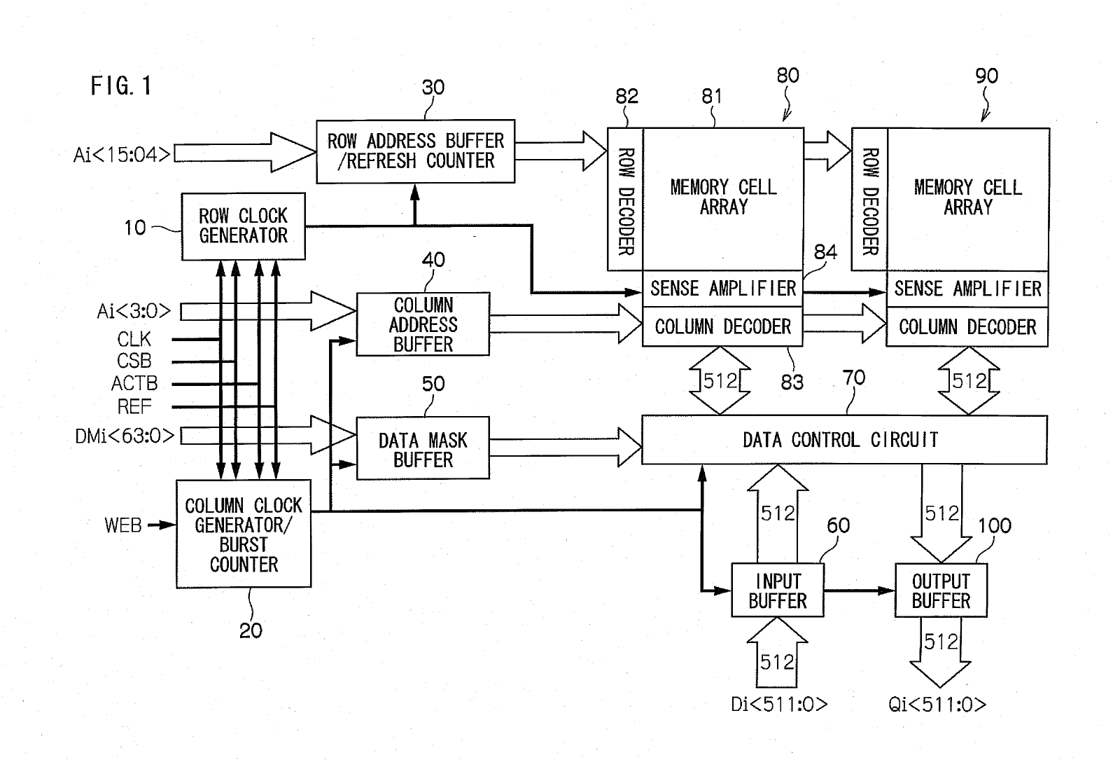

FIG. 1 is a view showing the configuration of the semiconductor memory device in which the present invention is implemented.

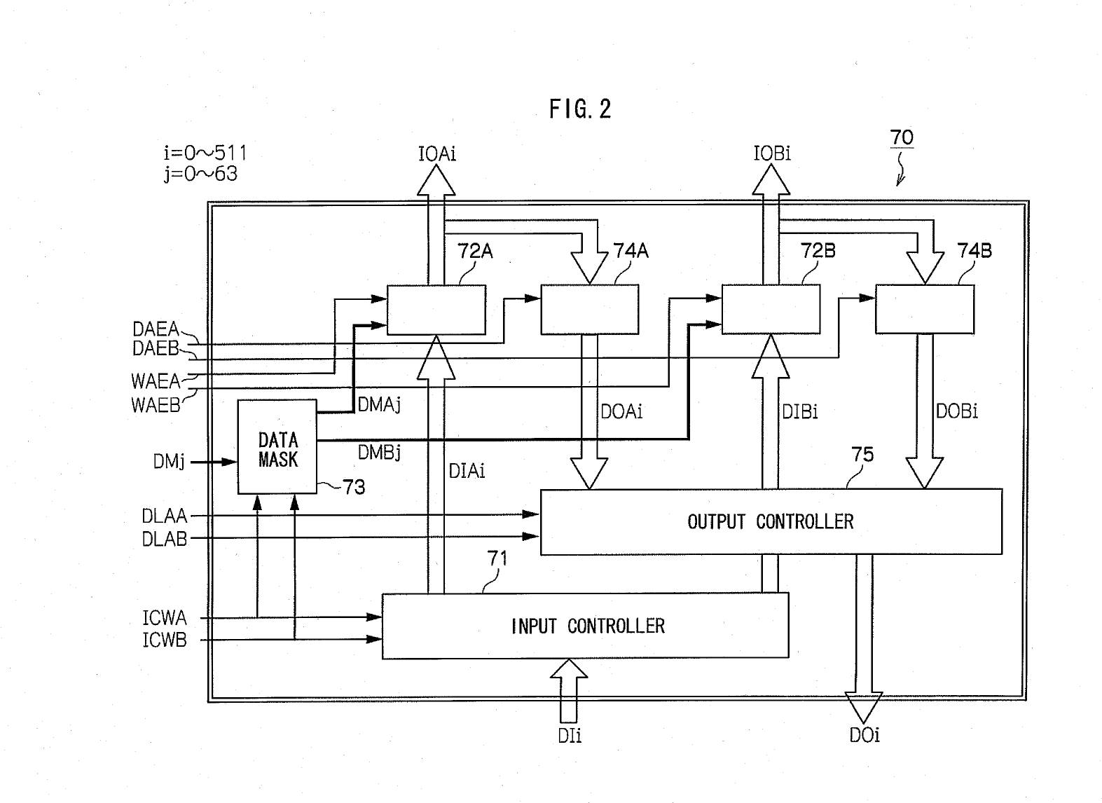

FIG. 2 is a view showing the detailed configuration of the data control circuit.

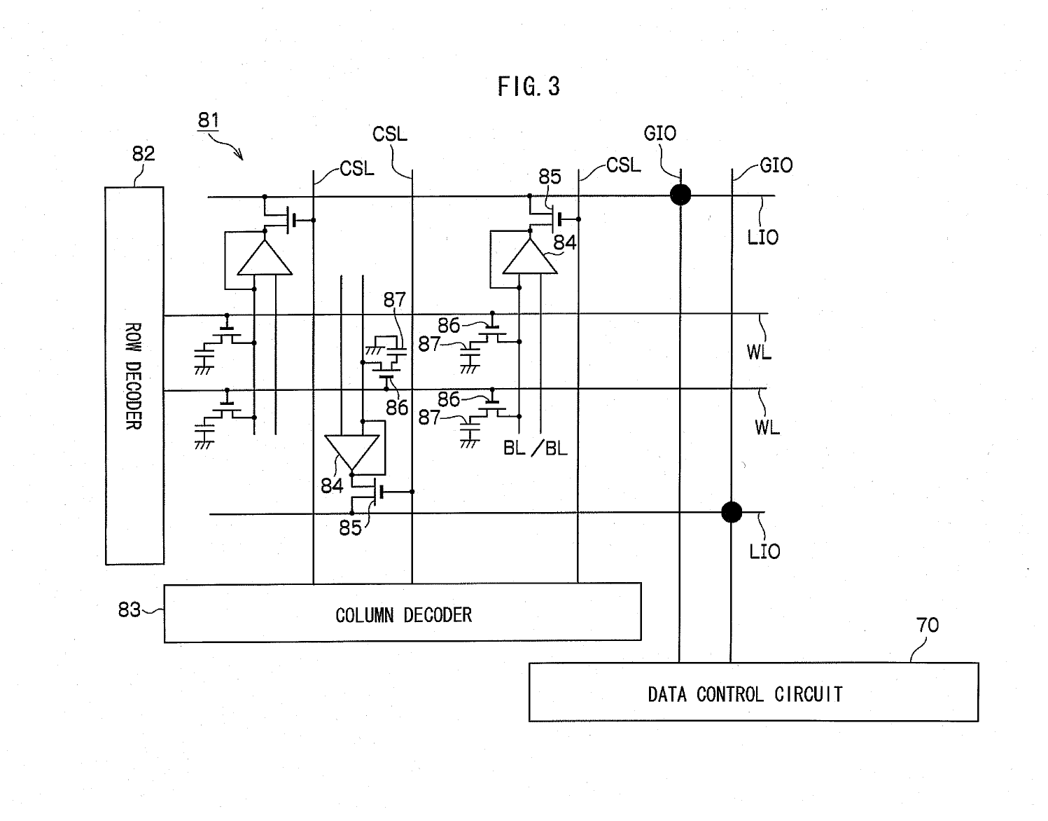

FIG. 3 is a view showing the detailed configuration of the memory cell array.

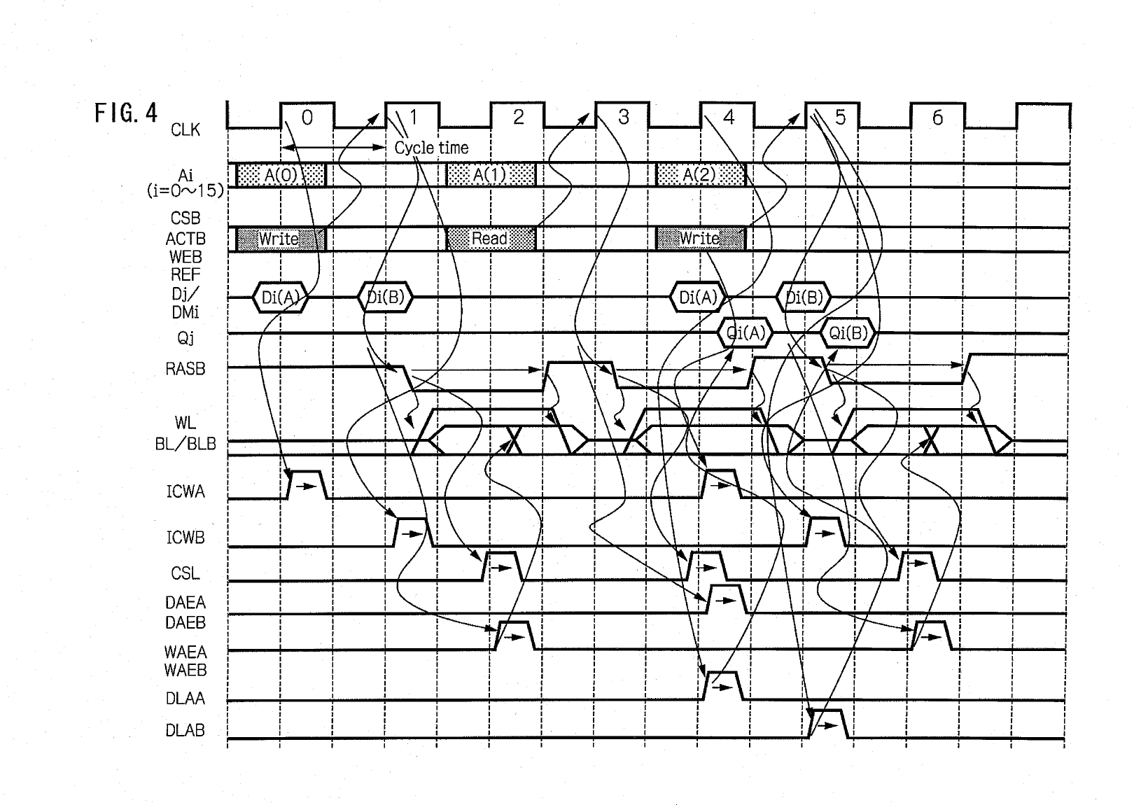

FIG. 4 is a timing chart of external signals as well as internal signals of the semiconductor memory device in which the present invention is implemented as the “first embodiment”.

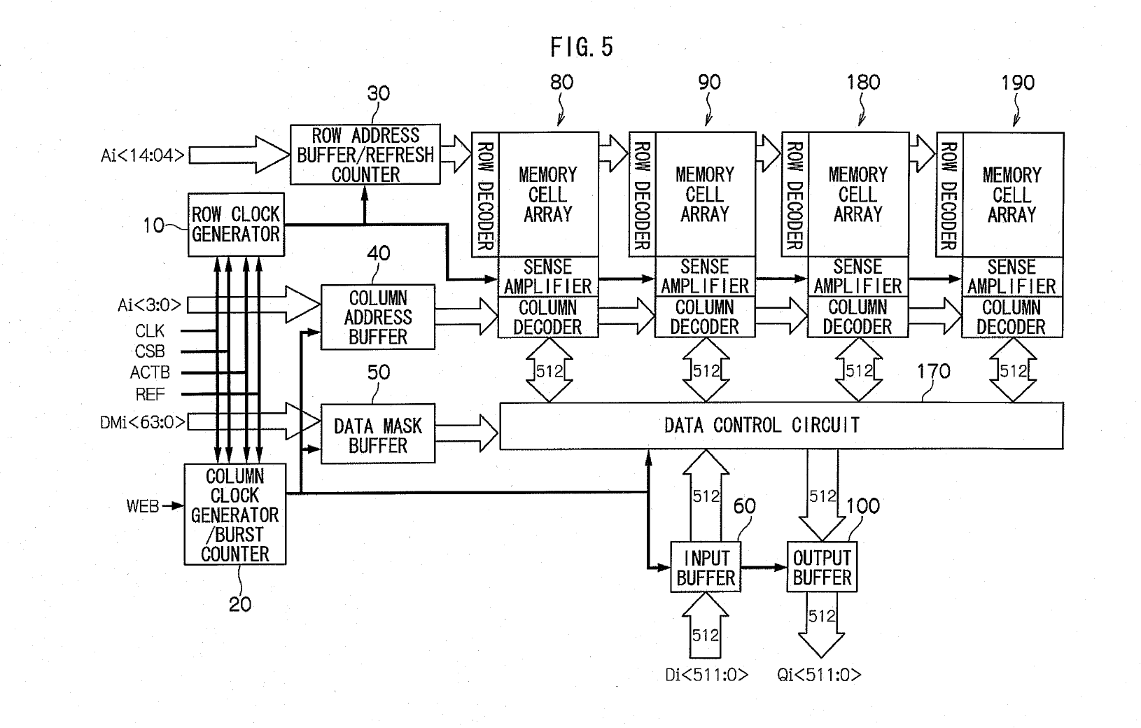

FIG. 5 is a view showing the configuration of the semiconductor memory device in which the present invention is implemented as the “second embodiment”.

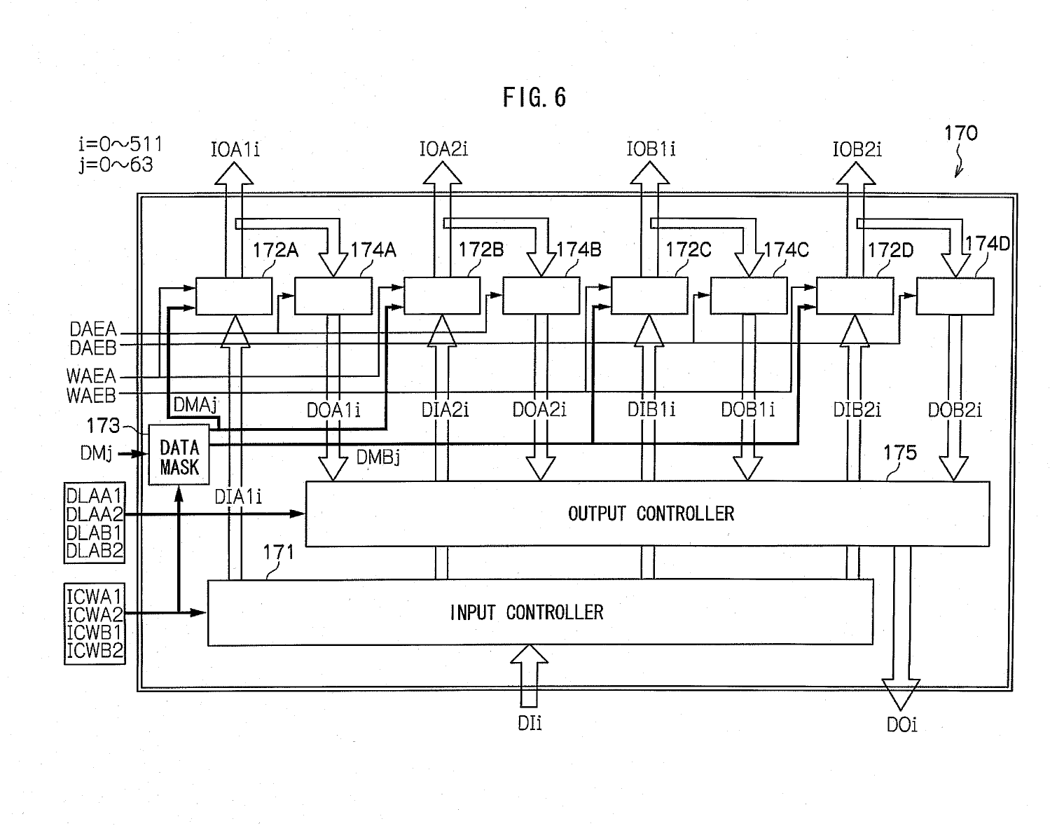

FIG. 6 is a block diagram showing the configuration of the data control circuit.

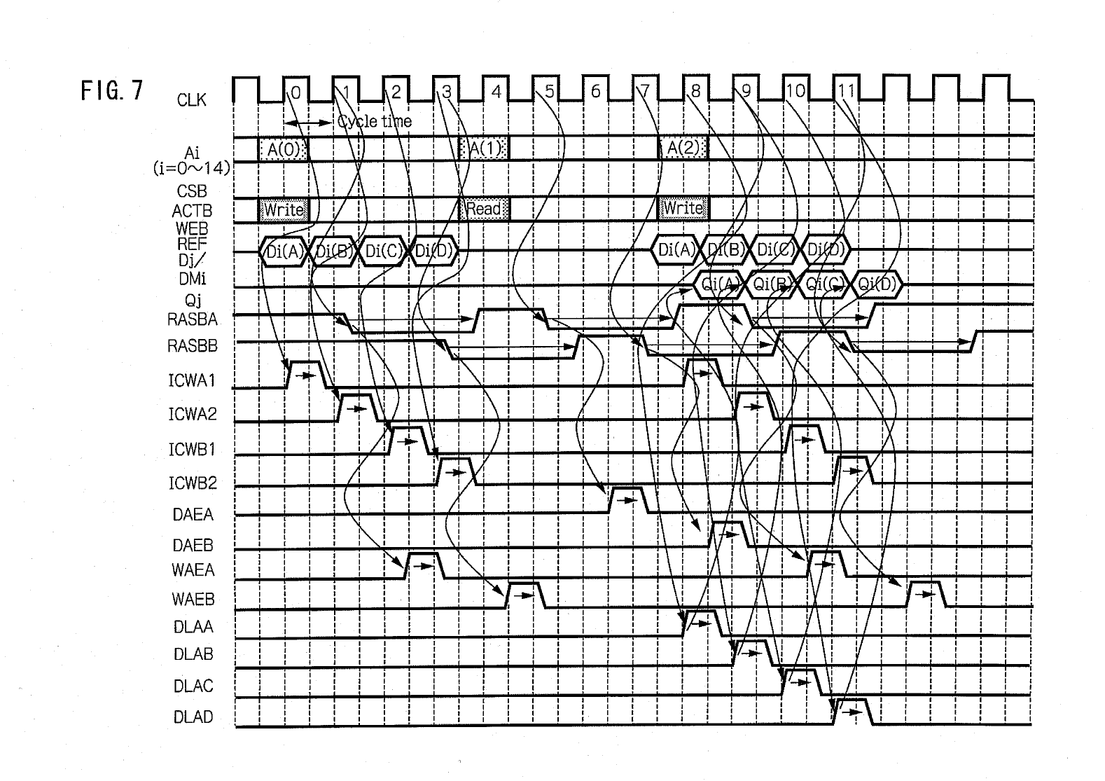

FIG. 7 is a timing chart of external signals as well as internal signals of the semiconductor memory device in which the present invention is implemented as the “second embodiment”.

### BEST MODE FOR CARRYING OUT THE INVENTION

Hereinafter, the exemplary embodiment of the present invention will be described in detail with reference to the drawings.

### First Embodiment

FIG. 1 is a view showing the configuration of the semiconductor memory device in which the present invention is implemented. The semiconductor memory device comprises the row clock generator 10 which generates the row clock, the column clock generator/burst counter 20 which generates the column clock or counts the burst, the row address buffer/refresh counter 30 which temporarily stores the 12-bit row address Ai<3:0> or counts the number of refreshes, the column address buffer 40 which temporarily stores the 4-bit column address Ai<3:0>, and the data mask buffer 50 which temporarily stores the data mask.

Also, the above-mentioned semiconductor memory device comprises the input buffer 60 which temporarily stores the data which is input from outside in a set of 512-bit signals, data control circuit 70 which outputs the data supplied by the input buffer 60, dividing it into two parallel data of a set of 512-bit signals each, or converting such two parallel data of a set of 512-bit signals each which are input to serial data, the first and second memory banks 80 and 90 to store the data provided by the above-mentioned data control circuit 70, and the output buffer 100 which temporarily stores the serial data in a set of 512-bit signals output from the data control circuit 30 and externally output such data in a set of 512-bit signals.

In the first embodiment as well as in the second embodiment which will be explained later, the memory device which writes and reads the data in a set of 512-bit signals is taken as an example. However, the present invention can be applied to semiconductor memory devices which write and read larger bit size of data than a set of 512-bit signals, such as in a set of 1024-bits signals, a set of 2048-bits signals, and a set of 4096-bits signals.

The row clock generator 10 generates the row clock which synchronizes the row address based on the externally provided clock (CLK), the chip select signal (CSB), the act command (ACTB), and refresh signal (REF), and provides the row clock to the row address buffer/refresh counter 30 and to the first and second memory banks, 80 and 90.

The column clock generator/burst counter 20 generates the column clock which synchronizes the column address based on the clock (CLK), the chip select signal (CSB), the act command (ACTB), and the refresh signal (REF), and the write enable signal (WEB), and provides the column clock to the column address buffer 40 and to the first and second memory banks, 80 and 90.

The row address buffer/refresh counter 30 synchronizes with the row clock generated by the row clock generator 10 and temporarily store the row address Ai (i=4-15) provided externally, and then, provides that row address to the first and second memory banks, 80 and 90. Also, the row address buffer/refresh counter 30 counts the number of refreshes conducted by the first and the second memory banks, 80 and 90.

The column address buffer 40 synchronizes with the column clock generated by the column clock generator/burst counter 20 and temporarily store the column address Ai (i=0-3) provided externally, and then, provides that column address to the first and second memory banks, 80 and 90.

The data mask buffer 50 temporarily stores the externally provided data mask, and then, provides the data mask to the data control circuit 70.

The first memory bank 80 comprises general-purpose DRAM chips. The first memory bank 80 comprises a memory cell array 81 which consists of a plurality of memory cells disposed in a matrix form, a row decoder 82 which selects the row address, a column decoder 83 which selects the column address, and the sense amplifier 84 which amplifies the memory cell supply voltage when reading the data. The second memory bank 90 has the same configuration as the first memory bank 80, so its detailed explanation is omitted.

FIG. 2 is a view showing the detailed configuration of the data control circuit 70. The data control circuit 70 comprises the input controller 71 which converts serial data to parallel data, the W amplifier 72A which supplies the data supplied by the data control circuit 70 to the first memory bank 80, the W amplifier 72B which supplies the data supplied by the data control circuit 70 to the second memory bank 90, the data mask 73, the D amplifier 74A which supplies data read from the first memory bank 80 to the output controller 75 which will be explained later, 74B which supplies data read from the second memory bank 90 to the output controller 75, and the output controller 75 which converts the data supplied by D amplifiers 74A and 74B to serial data and output such data.

The input controller 71 obtains the serial data DIi (i=0-511) from the input buffer 60, synchronizing with the ICMA (Internal Write Clock #A) signal and the ICWB (Internal Write Clock #B) signal. And the input controller 71 divides the serial data DIi into two sets of data (parallel data) which are DIAi and DIBi (i=0-511), and provides DIAi to the W amplifier 72A and DIBi to the W amplifier 72B.

The W amplifier 72A is activated when the activating signal WAEA is supplied, then, it amplifies the data DIAi supplied by the input controller 71, and supplies the data IOAi (i=0-511) to the first memory bank 80. Also, W amplifier 72B is activated when the activating signal WAEB is supplied, then, it amplifies the data DIBi supplied by the input controller 71, and supplies the data IOBi (i=0-511) to the second memory bank 90.

In this embodiment, WEAE and WAEB clock cycles are ½ of ICWA and ICWB clock cycles. Therefore, W amplifiers 72A and 72B write each data to the first and second memory banks 80 and 90 with double the speed of the clock cycle of the input data DIi.

Thus, the data control circuit 70 is able to write the data DIAi and DIBi to the first and second memory banks 80 and 90 with much faster speed than the input data DIi by making the clock cycles for the divided data DIAi and DIBi double the speed of the input data DIi clock cycle.

FIG. 3 is a view showing the detailed configuration of the memory cell array 81. The memory cell array 81 comprises a plurality of word lines disposed in a row direction and a plurality of column selection lines CSL disposed in the column direction, the first FET 85 which is activated when a signal (voltage) is supplied to the column selection lines CSL, the second FET 86 which is activated when a signal (voltage) is supplied to the word lines WL, the condenser 87 which corresponds with one memory cell, the local input/output lines LIO and the global input/output lines GIO.

The first FET 85 drain is connected to the local input/output lines and its source is connected to the output terminal of the sense amplifier 84, and its gate is connected to the column selection line CSL.

The sense amplifier 84 comprise the data input terminal BL to which data is input, control terminal/BL to which a threshold signal is input to compare with the input data from the data input terminal BL, and the output terminal. The sense amplifier outputs “1” when the input data is higher than the threshold value and it outputs “0” when the input data is lower than the threshold value via the output terminal. Also, the data input terminal and the data output terminal are in short.

The second FET 86 drain is connected to the data input terminal of the sense amplifier 84 and its gate is connected to the word line WL. One side of the terminal of the condenser 87 is connected to the source of the second FET 86 and other terminals are grounded.

The row decoder 82 outputs signals to the word line corresponding with the row address supplied by the row address buffer refresh counter 30 shown in FIG. 1, and after a certain amount of time, it stops outputting the signal. The row decoder 82 has an internal delay device to automatically reset the signal after such signal is output so that it operates only by act commands. Also, the column decoder 83 provides a single column address selection signal to the column selection line CSL corresponding with the column address supplied to the column decoder 83.

FIG. 4 is a timing chart of external signals as well as internal signals of the semiconductor memory device in which the present invention is implemented as the “first embodiment”. External signals of the semiconductor memory device are the clock (CLK), the address indicating either the row address or the column address (AI:i=1, 2, . . . 15), the chip selection signal (CSB), the act command (ACTB), the write-enable signal (WEB), the refresh signal commanding to refresh the first and the second memory banks 80 and 90 (REF), the input data (Di), and the output data (Qi).

Internal signals are the inverted RAS signal (RASB), the word line signal (WL), the sense amplifier signal (BL: input terminal signal, /BL: control terminal signal), the clock signal to obtain input data (ICWA, ICWB), the column address selection signal (CSL), the D amplifier activation signal (DAEA, DAEB), the W amplifier activation signal (WAEA, WAEB), and the output data latch signal (DLAA, DLAB).

With the clock cycle time CLK0, the address A(0), the act command for writing, and the data Di(A) are supplied to the semiconductor memory device. Right after that, ICWA starts up, synchronizing with CLK0. Therefore, the input controller 71 of the data control circuit 70 shown in FIG. 3 supplies data Di (A) (DIAi) provided by the input buffer 60 to the W amplifier 72A, synchronizing with ICWA.

With the clock cycle time CLK1, the data Di(B) which is the next data after DI8(A) is supplied to the semiconductor memory device. Right after that, RASB falls, and ICWB rises, synchronizing with CLK1. RASB is a signal which is generated inside the row decoder 82 shown in FIG. 1 and it falls synchronizing with the act command, and automatically rises after a certain amount of time by the delay device which is not indicated in the figure. In this case, the row decoder 82 supplies a predetermined level of signal WL to the word line WL indicated by the row address while RASB falls.

On the other hand, the input controller 71 in the data control circuit 70 shown in FIG. 3 supplies the data Di(B) (DIBi) provided by the input buffer 60 to the W amplifier 72B, synchronizing with ICWB.

With the clock cycle time CLK2, the address A (1) and a reading act command is supplied to the semiconductor memory device. Also, with the clock cycle time CLK2, CSL rises, synchronizing with the fall of RASB with the clock cycle time CLK1 which is mentioned above. Thus, the column decoder 83 shown in FIG. 2 supplies the CSL which rises to the column address selection line CSL corresponding with the column address, and turns on the first FET 85 which is connected to the column selection line CSL.

Also, WAEA and WAEB rise, synchronizing with the above-mentioned CLK1. Thus, W amplifiers 72A and 72B supply the data Di(A) and Di(B) provided by the input controller 71 to the first and second memory banks 80 and 90, synchronizing with WAEA and WAEB. As a result, the data flow to the global input/output lines GIO and the local input/output lines LIO, and the data (voltages) are supplied to the condenser 87 via the first FET 85 and the second FET 86 which are turned on.

Thus, the semiconductor memory device starts writing of the first data Di(A) and the second data Di(B), synchronizing with the second clock CLK2, after a reading act command at CLK0.

With the clock cycle time CLK3, RASB falls, synchronizing with the reading act command at CLK2, and after a certain amount of time, it rises automatically. At this time, the row decoder 82 provides a predetermined level of signal WL to the word line WL indicated by the row address while RASB falls. As a result, the second FET 86 corresponding with the row address shown in FIG. 2 is turned on.

With the clock cycle time CLK4, the address A(2), he writing act command, and the data Di(A) are supplied to the semiconductor memory device. ICWA rises synchronizing with the writing act command. Also, with the clock cycle time CLK4, CSL rises, synchronizing with the fall of RASB at CLK3 as formerly mentioned. Thus, the column decoder shown in FIG. 2 supplies the signal CSL to the column selection line CSL corresponding with the column address, and turns on the first FET 85 which is connected to the column selection line CSL.

Thus, the electric charge accumulated in the condenser 87 is supplied to the data input terminal BL of the sense amplifier 84 via the second FET 86. The sense amplifier 84 compares the voltage of the data input terminal BL with the threshold voltage of the control terminal/BL and it outputs “1” (high level signal) when the voltage of the data input terminal BL is higher than the threshold voltage, and outputs “0” (low level signal) when the voltage of the data input terminal BL is lower than the threshold voltage. Thus, the signal which shows the comparison results by the sense amplifier 84 is supplied to the data control circuit 70 via the first FET 85, the local input/output lines LIO, and the global input/output lines GIO.

Also, with the clock cycle time CLK4, DAEA and DAEB rise synchronizing with the above-mentioned CLK3. By this, D amplifiers 74A and 74B of the data control circuit 70 provide the data read from the first and the second memory banks 80 and 90 to the output controller 75, synchronizing with DAEA and DAEB.

Further, when DLAA rises synchronizing with the rising of CLK4, the output controller 75 latches the output data, synchronizing with the said DLAA, and supplies the data to the output buffer 100 shown in FIG. 1. And the output buffer 100 outputs the Data Qi (A) at CLK4 as shown in FIG. 4. Also, when DLAB rises synchronizing with CLK5, the output controller 75 latches the output data, synchronizing with the said DLAB, and supplies the data to the output buffer 100 shown in FIG. 1. And the output buffer 100 outputs the Data Qi (B) at CLK5 as shown in FIG. 4.

Thus, the semiconductor memory device starts reading the data, synchronizing with the second CLK4, after the act command given at CLK2. Therefore, even the semiconductor memory device writes and reads the data alternately, it does so, synchronizing with the second clock after the act command is given, so there are no timing gaps between such writing and reading.

Based on the explanation above, as for the semiconductor memory device described in the first embodiment, the row decoder increases the voltage of the word line WL when it receives the act command and then, automatically reduces the voltage after a certain period of time, so it does not need another command to reduce the voltage of the word line WL. Thus, even when the row address changes during random access, there is no need to wait for the command to reduce the voltage of the word line WL, which reduces the random access time.

Also, above-mentioned semiconductor memory device can read and write serial data from and to each memory banks with much faster speed than the input and output data by making the clock cycle of the parallel data written into or read from the first and second memory banks 80 and 90 double the speed than the clock cycle of input and output data.

Further, since above-mentioned semiconductor memory device has the data input buffer 60 and the data output buffer 100 independent from each other, bursts for writing and reading the data can access with not time lag. Also, the semiconductor memory device can write the data into memory bank 80 and 90 one after another, dividing the data into 512-bit chunks, convert the 512-bit data read from memory banks 80 and 90 to serial data and reads it to outside one after another. In other words, the semiconductor memory device fixes the accessing order to the memory banks and writes or reads the data with the address data which consists of small bits of data, which requires fewer address pins than conventional devices.

Thus, above-mentioned semiconductor memory device can achieve high-speed random access utilizing general-purpose DRAMS as well as can write and read a massive amount of data.

### Second Embodiment

Next is an explanation of the second embodiment of the present invention. Where there are common portions with the first embodiment, it is explained as such and details are omitted. In the first embodiment, the memory device has two memory banks. In the second embodiment, the memory device has four memory banks.

FIG. 5 is a view showing the configuration of the semiconductor memory device in which the present invention is implemented as the “second embodiment”. This semiconductor memory device has the third memory bank 180 and the fourth memory bank 190 in addition to the configuration shown in FIG. 1, and in stead of the data control circuit 70 shown in FIG. 1, it has the data control circuit 170. The third and the fourth memory banks 180 and 190 are configured in the same way as shown in FIG. 3.

FIG. 6 is a block diagram showing the configuration of the data control circuit 170. The data control circuit 170 comprises the input controller 171 which converts serial data to four sets of parallel data, the W amplifier 172A which supplies the data provided by the input controller 171 to the first memory bank 80, the W amplifier 172B which supplies the data provided by the input controller 171 to the second memory bank 90, and the W amplifier 172C which supplies the data provided by the input controller 171 to the third memory bank 180, and the W amplifiers 172D which supplies the data provided by the input controller 171 to the fourth memory bank 190.

Also, the data control circuit 170 comprises the data mask 173, the D amplifier 174A which supplies the data read from the first memory bank 80 to the output controller 175 which will be explained later, the D amplifier 174B which supplies the data read from the second memory bank 90 to the output controller 175, 174C which supplies the data read from the third memory bank 180 to the output controller 175, 174D which supplies the data read from the fourth memory bank 190 to the output controller 175, and the output controller 175 which converts the data supplied by the D amplifiers 174A, 174B, 174C, and 174D to serial data and output such data.

The input controller 171 obtains the serial data DIi (i=0-511) from the input buffer 60 synchronizing with the written data capture clock signal ICWA1, ICWA2, ICWB1, and ICWB2. And the input controller 171 divides the serial data DIi into four sets of data (parallel data) which are DIA1i, DIA2i, DIB1i, DIB2i (i=0-511), and supplies the DIA1i to the W amplifier 172A, DIA2i to the W amplifiers 172B, DIB1i to the W amplifiers to 172C, and DIB2i to the W amplifiers 172D.

The W amplifiers 172A and 172B are activated when the activation signal WAEA is supplied, and they amplify the data supplied by the input controller 71, and supply each of the data IOA1i and IOA2i (i=0-511) to the first memory bank 80 and to the second memory bank 90. Also, the W amplifier 172C and 172D are activated when the activation signal WAEB is supplied, and they amplify the data supplied by the input controller 71, and supply each of the data IOB1i and IOBi2 (i=0-511) to the third memory bank 180 and to the fourth memory bank 190.

In this embodiment, the clock cycles of WAEA and WAEB are ¼ of the speed of the clock cycles of ICWA and ICWB. Therefore, the W amplifiers 172A, 172B, 172C, and 172D can write each data to four memory banks from 80, 90, 180, to 190 four times faster than the clock cycle of the input data DIi.

Therefore, the data control circuit 170 can write and read the data DIA1i, DIA2i, DIB1i, and DIB2i to and from the four memory banks from 80, 90, 180, to 190 much faster than the input data DIi by making the clock cycles of DIA1i, DIA2i, DIB1i, and DIB2i four times faster than the clock cycle of the input data DIi.

FIG. 7 is a timing chart of external signals as well as internal signals of the semiconductor memory device in which present invention is implemented as the “second embodiment”. The external signals and internal signals are the same as shown in FIG. 4.

With the clock cycle time CLK0, the address (A), the writing act command, and the data Di (A) are supplied to the semiconductor memory device. Right after that, the ICWA1 rises synchronizing with CLK0. Therefore, the input controller 171 of the data control circuit 170 shown in FIG. 6 supplies the data Di(A) (DIA1i) provided by the input buffer 60 to the W amplifiers 172A, synchronizing with ICWA1.

With the clock cycle time CLK1, the data Di (B) which is the next data after the data Di(A) is supplied to the semiconductor memory device. Right after that, the ICWA2 rises synchronizing with CLK1. Therefore, the input controller 171 supplies the data Di(B) (DIA2i) provided by the input buffer 60 to the W amplifiers 172B, synchronizing with ICWA2.

Further, RASBA falls synchronizing with CLK1. RASBA is a signal which is generated inside the row decoder shown in FIG. 5 and it falls synchronizing with the act command, and automatically rises after a certain amount of time by the delay device which is not indicated in the figure. In this case, the row decoder supplies a predetermined level of signal WL to the word line WL indicated by the row address while RASBA falls. As a result, the second FET 86 shown in FIG. 2 which corresponds with the row address is turned on.

With the clock cycle time CLK2, the data Di(C) are supplied to the semiconductor memory device. Right after that, ICWB1 rises, synchronizing with CLK2. Therefore, the input controller 171 supplies the data Di (C) (DIB1i) provided by the input buffer 60 to the W amplifiers 172C, synchronizing with ICWB1. On the other hand, the column decoder supplies a certain signal (voltage) to the column selection line CSL which corresponds with the column address and turns on the first FET 85 which is connected to the column selection line CSL.

Further, after a half cycle clock time from the rise of the clock cycle time CLK2, WAEA rises synchronizing with the fall of RASBA at CLK1. Thus, the W amplifiers 172A and 172B supply the data DIA1i and DIA2i provided by the input controller 171 to the first and second memory banks 80 and 90, synchronizing with WAEA. As a result, the data flows to the global input/output lines GIO and the local input/output lines LIO, and the data (voltage) is supplied to the condenser 87 via the first FET 85 and the second FET 86 which are turned on.

Thus, the semiconductor memory device starts writing the first data DIA1i and the second data DIA2i after the writing act command at CLK0, synchronizing with the second clock CLK2.

With the clock cycle time CLK3, the data Di(D) are supplied to the semiconductor memory device. Right after that, ICWB2 rises, synchronizing with CLK3. Therefore, the input controller 171 supplies the data Di (D) (DIB2i) provided by the input buffer 60 to the W amplifiers 172D, synchronizing with ICWB2.

Further, RASBB falls synchronizing with CLK3. RASBB, similarly with RASBA, is a signal which is generated inside the row decoder shown in FIG. 5 and it falls synchronizing with the act command, and automatically rises after a certain amount of time by the delay device which is not indicated in the figure. In this case, the row decoder supplies a predetermined level of signal WL to the word line WL indicated by the row address while RASBB falls. As a result, the second FET 86 shown in FIG. 2 which corresponds with the row address is turned on. On the other hand, the column decoder supplies a certain signal (voltage) to the column selection line CSL which corresponds with the column address and turns on the first FET 85 which is connected to the column selection line CSL.

With the clock cycle time CLK4, the address A (1) and the reading act command is supplied to the semiconductor memory device.

On the other hand, after a half cycle clock time from the rise of the clock cycle time CLK4, WAEB rises synchronizing with the fall of RASBB. Thus, the W amplifiers 172C and 172D supply the data DIB1i and DIB2i provided by the input controller 171 to the third and fourth memory banks 180 and 190, synchronizing with WAEB. As a result, the data flows to the global input/output lines GIO and the local input/output lines LIO, and the data (voltage) is supplied to the condenser 87 via the first FET 85 and the second FET 86 which are turned on.

Also, as mentioned above, WAEB is 2 clocks behind WAEA. Therefore, the semiconductor memory device starts writing the third data DIB1i and the fourth data DIB2i 2 clocks after writing the first data DIA1i and the second data DIA2i.

With the clock cycle time CLK5, RASBA falls. Then, the row decoder supplies a predetermined level of signal WL to the word line WL indicated by the row address while RASBA falls. As a result, the second FET 86 shown in FIG. 2 which corresponds with the row address is turned on. On the other hand, the column decoder provides a predetermined level of signal (voltage) to the column selection line CSL which corresponds with the column address and turns the first FET 85 on which is connected to the column selection line CSL.

Thus, the electric charge accumulated in the condenser 87 is supplied to the data input terminal BL of the sense amplifier 84 via the second FET 86. The sense amplifier 84 compares the voltage of the data input terminal BL with the threshold voltage of the control terminal/BL and it outputs “1” (high level signal) when the voltage of the data input terminal BL is higher than the threshold voltage, and outputs “0” (low level signal) when the voltage of the data input terminal BL is lower than the threshold voltage. Thus, the signal which shows the comparison results by the sense amplifier 84 is supplied to the data control circuit 70 via the first FET 85, the local input/output lines LIO, and the global input/output lines GIO.

After a half cycle clock time from the rise of the clock cycle time CLK6, DAEB rises synchronizing with the fall of RASBA. Thus, the D amplifiers 174A and 174B supply the data provided by the first and second memory banks 80 and 90 to the output controller 175, synchronizing with DAEB. As a result, the data flows to the global input/output lines GIO and the local input/output lines LIO, and the data (voltage) is supplied to the condenser 87 via the first FET 85 and the second FET 86 which are turned on.

Further, when DLAA rises synchronizing with the rise of CLK8, the output controller 75 latches the output data, synchronizing with the said DLAA, and supplies the data to the output buffer 100 shown in FIG. 5. And the output buffer 100 outputs the Data Qi (A) at CLK8 as shown in FIG. 7. And the output buffer 100 outputs the Data Qi (B), Qi (C), and Qi(D) at each clock cycle.

Thus, the semiconductor memory device starts reading the data, synchronizing with the second CLK6, after the act command given at CLK4. Therefore, even the said semiconductor memory device writes and reads the data one after another, it does so, synchronizing with the second clock after the act command is given, so there are no timing gaps between such writing and reading.

Based on the explanation above, the semiconductor memory device described in the second embodiment is similar to that of the first embodiment in such a way that the row decoder increases the voltage of the word line WL when it receives the act command and then, automatically reduces the voltage after a certain period of time, so even when the row address changes during random access, there is no need to wait for the command to reduce the voltage of the word line WL, which reduces the random access time.

Also, above-mentioned semiconductor memory device can read and write the serial data from and to each memory banks with much faster speed than the input and output data by making the clock cycle of the parallel data written into or read from each memory bank four times the speed of the clock cycle of the input and output data.

Further, similarly with the first embodiment, since above-mentioned semiconductor memory device has the data input buffer 60 and the data output buffer 100 independent from each other, bursts for writing and reading the data can access with no time lag. Thus, above-mentioned semiconductor memory device can achieve high-speed random access utilizing general-purpose DRAMS as well as can write and read a massive amount of data. Also, above-mentioned semiconductor memory device fixes the accessing order to four memory banks, which can require fewer address pins than conventional devices.

Needless to say, the present invention is not limited to above-mentioned embodiments specifically but can be applied to any design modification which fall within the patent claim coverage. For example, above-mentioned embodiments have either two or four memory banks, but it can comprise any number of a plurality of memory banks without any limitation.

Also, the present invention can be implemented in such a way that the first and the second embodiments can be switched back and forth. For example, the semiconductor memory device can be configured as shown in FIG. 5 and may have an activation circuit to activate any desired memory banks, from memory banks 80, 90, 180, to 190. In this case, the activation circuit can activate only the first and second memory banks 80 and 90 to write and read the data in the first mode, and activate four memory banks from 80, 90, 180 to 190 to write and read the data in the second mode.

### DESCRIPTION OF REFERENCE NUMERALS

70: Data control circuit
71, 171: Input controller
72A, 72B, 172A, 172B, 172C, 172D: W amplifiers
73, 17: Data mask
74A, 74B, 174A, 174B, 174C, 174D: D amplifiers
75, 175: Output controller
80: First memory bank
81: Memory cell array
82: Row decoder
83: Column decoder
84: Sense amplifier
85: First FET
86: Second FET
87: Condenser
90: Second memory bank
180: Third memory bank
190: Fourth memory bank

1. A semiconductor memory device comprising:
a plurality of memory cells disposed in the row direction and the column direction,
a plurality of first lines by which supply voltages are supplied in order to select memory cells disposed in the row direction among the plurality of cells,
a plurality of second lines by which supply voltages are supplied in order to select memory cells disposed in the column direction among the plurality of cells,
data lines which input and output data to the selected memory cells,
a first power voltage supply circuit which supplies the predetermined supply voltages for a certain period of time to the first lines corresponding with an externally input row address synchronizing with an act command,
a second power voltage supply circuit which supplies the predetermined supply voltages to the second lines corresponding with an externally input column address synchronizing with the act command,
m pieces of memory banks (m is a natural number larger than 2) which write or read the data into or from the memory cells which are selected one after another in the row or column directions,
data input circuits in which a plurality of bits of serial data which is larger than 512 bits to be written in the pieces of memory banks,
data output circuits which read the data from the m pieces of memory banks and output in a form of the plurality of bits of serial data which is larger than 512 bits, and data conversion circuits which convert the serial data input in the data input circuits to parallel data so that it can be written in each memory bank or to convert each parallel data read from each memory bank to serial data so that such data are supplied to the data output circuits.

2. A semiconductor memory device according to claim 1, wherein a clock cycle of the parallel data is m times larger than a clock cycle of the serial data

3. A semiconductor memory device according to claim 1 or claim 2,
wherein when m=2, each memory bank starts writing or reading the input data, synchronizing with a next clock after the clock with which the act command is supplied.

4. A semiconductor memory device according to claim 1 or 2 wherein
when m=4, a first memory banks and a second memory banks start writing the input data of a predetermined bit size, synchronizing with the next clock after the clock with which the act command is supplied,
a third memory banks and a fourth memory banks, synchronizing with a clock which is three clocks later than the clock of the formerly mentioned act command, start writing the input data of a predetermined bit size which follows right after the input data,
the first memory banks and the second memory banks, synchronizing with the next clock after the clock of the reading command which follows the writing act command, start reading the data of the predetermined bit size,
the third memory banks and the fourth memory banks, synchronizing with a clock which is three clocks later than the clock of the reading act command, start reading the data of the predetermined bit size.

5. A semiconductor memory device according to claim 1 or 2 comprising:
the data activation circuit which activates predetermined memory banks from the m pieces of memory banks, and
only the memory banks activated by the activation circuits write or read the data.

6. A semiconductor memory device according to claim 5 where in the activation circuit switches the activated memory banks one after another.
